(19) United States
(12) Patent Application Publication
(10) Pub. No.: US 2019/0150296 A1
(43) Pub. Date: May 16, 2019

(54) ADDITIVE MANUFACTURING TECHNOLOGY MICROWAVE VERTICAL LAUNCH

(71) Applicant: RAYTHEON COMPANY, Waltham, MA (US)

(72) Inventors: Andrew R. Southworth, Lowell, MA (US); Thomas V. Sikina, Acton, MA (US); John P. Haven, Lowell, MA (US); James E. Benedict, Lowell, MA (US); Kevin Wilder, Derry, NH (US)

(21) Appl. No.: 15/988,296

(22) Filed: May 24, 2018

Related U.S. Application Data
(60) Provisional application No. 62/636,364, filed on Feb. 28, 2018.
(60) Provisional application No. 62/636,375, filed on Feb. 28, 2018.
(60) Provisional application No. 62/584,260, filed on Nov. 10, 2017.
(60) Provisional application No. 62/584,264, filed on Nov. 10, 2017.

(51) Int. Cl. H05K 3/34; H05K 1/02

(52) U.S. Cl. CPC H05K 3/3426; H05K 1/024; H05K 2201/083; H05K 1/0243; H05K 1/0242

(57) ABSTRACT

Electromagnetic circuit structures and methods are provided for a circuit board that includes a hole disposed through a substrate to provide access to an electrical component, such as a signal trace line (or stripline), that is at least partially encapsulated (e.g., sandwiched) between substrates. The electrical component includes a portion substantially aligned with the hole, and an electrical conductor is disposed within the hole. The electrical conductor is soldered to the portion of the electrical component.

### CROSS-REFERENCE TO RELATED APPLICATIONS

This application claims the benefit under 35 U.S.C. § 119(e) of co-pending U.S. Provisional Patent Application No. 62/584,260 titled SPIRAL ANTENNA AND RELATED FABRICATION TECHNIQUES filed on Nov. 10, 2017, U.S. Provisional Patent Application No. 62/584,264 titled ADDITIVE MANUFACTURING TECHNOLOGY (AMT) LOW PROFILE RADIATOR filed on Nov. 10, 2017, U.S. Provisional Patent Application No. 62/636,364 titled SNAP-RF INTERCONNECTIONS filed on Feb. 28, 2018, and U.S. Provisional Patent Application No. 62/636,375 titled ADDITIVE MANUFACTURING TECHNOLOGY (AMT) LOW PROFILE SIGNAL DIVIDER filed on Feb. 28, 2018, each of which is herein incorporated by reference in its entirety for all purposes.

### BACKGROUND

Radio frequency (RF) and electromagnetic circuits may be manufactured using conventional printed circuit board (PCB) processes. Some RF and electromagnetic circuits may include interconnections between layers (e.g., laminates, substrates, etc.) of a circuit, such as a circuit board, for example to convey a signal from one layer of the circuit to another. Conventional PCB manufacturing processes may include an electroplating process to provide an electrical conductor between layers, e.g., a via, which may require multiple differing steps, including baths in hazardous materials, and may require multiple iterations, extensive labor, etc., all leading to higher cost and slower turnaround time. Additionally, conventional PCB manufacturing processes have limited ability to allow for small feature sizes, such as signal trace dimensions and dimensions of dielectric materials between conductors (e.g., dielectric thickness, inter-via spacing, etc.), thereby limiting the range of highest frequency signals that may be supported by such devices.

### SUMMARY

Aspects and embodiments described herein provide simplified circuit structures, and manufacturing methods thereof, for conveyance of electrical signals, especially radio frequency signals, between layers (e.g., vertically) of a circuit. Various embodiments of circuits in accord with those described herein may be constructed of, e.g., laminate or dielectric substrates, and may have circuit features, signal layers, ground planes, or other circuit structures therebetween. Further, various signal conductors and circuit structures may be fabricated more simply and with smaller feature sizes than conventional techniques. Such circuit structures are suitable for higher frequency operation into the millimeter wave range, as well as conventional microwave ranges. Circuits, structures, and fabrication methods described herein use subtractive and additive manufacturing technology to achieve smaller sizes and higher frequency operation.

According to one aspect, a circuit board is provided that includes a first substrate having a first surface, a second substrate having a second surface; the second surface facing the first surface, a hole disposed through the first substrate (e.g., the hole may be substantially normal to the first surface), an electrical component disposed adjacent each of the first surface and the second surface, the electrical component being at least partially encapsulated (e.g., sandwiched) between the first substrate and the second substrate, the electrical component having a portion substantially aligned with the hole, and an electrical conductor disposed within the hole, the electrical conductor having a first terminal end and a second terminal end, the first terminal end soldered to the portion of the electrical component.

In certain embodiments, the electrical conductor is a solid wire. The solid wire may be a copper wire.

Some embodiments include bonding material configured to bond the first substrate to the second substrate, directly or indirectly, at each of the first surface and the second surface. Accordingly, the first and second substrates may be bonded together to substantially encapsulate the electrical component. Various portions of the electrical component may extend to an exterior of one or more of the first substrate and/or the second substrate in various embodiments.

According to certain embodiments, the electrical component is a signal trace line formed of an electrically conductive material, and the portion substantially aligned with the hole forms a terminal covering to the hole. In some embodiments, the signal trace line may provide an input or an output for a radio frequency signal, and may extend to an exterior of one or more of the first substrate and/or the second substrate.

Various embodiments include a second electrical component having a portion soldered to the second terminal end of the electrical conductor. In some embodiments, the second electrical component may be one of a signal terminal, an electrical connector, a cable, and an electromagnetic radiator. The second electrical component may be surface mounted to a third surface. In some embodiments, the second electrical component may substantially encapsulated between two substrates, either or neither of which may be one of the first substrate or the second substrate.

Some embodiments include a ground plane disposed adjacent an opposing surface of the second substrate, the ground plane configured to provide an electromagnetic boundary condition to the signal trace line.

According to another aspect, a method of manufacturing an electromagnetic circuit is provided. The method includes providing a circuit feature upon a surface of at least one of a first substrate or a second substrate, forming a hole in at least one of the first substrate or the second substrate, the hole positioned to substantially align with a portion of the circuit feature, applying solder to at least one of an electrical conductor and the portion of the circuit feature, bonding the first substrate, directly or indirectly, to the second substrate, a bonded orientation of the first substrate and the second substrate being configured to at least partially encapsulate (e.g., sandwich) the circuit feature between the first substrate and the second substrate and to substantially align the hole with the portion of the circuit feature, the hole being positioned to provide access to the portion of the circuit feature, inserting the electrical conductor in the hole, and reflowing the solder to form an electrical connection between the electrical conductor and the portion of the circuit feature.

In certain embodiments, inserting the electrical conductor in the hole comprises inserting a segment of solid wire into the hole. The wire may be copper.

In various embodiments, providing the circuit feature upon a surface comprises milling an electrically conductive material from the surface to form the circuit feature. Milling the electrically conductive material from the surface to form the circuit feature may include milling the electrically conductive material to form a signal trace line.

According to various embodiments, the circuit feature is a first circuit feature, and the method further includes providing a second circuit feature having a second portion positioned to substantially align with an opposing opening of the hole, and applying solder to form an electrical connection between the electrical conductor and the second portion. In some embodiments, providing the second circuit feature includes milling an electrically conductive material to form an electromagnetic radiator. In some embodiments, providing the second circuit feature includes milling an electrically conductive material to form a signal terminal pad configured to be coupled to at least one of an electrical connector or an electrical cable.

According to another aspect, a circuit board is provided that includes a first dielectric substrate bonded directly or indirectly to a second dielectric substrate, a signal trace line formed of an electrically conductive material disposed adjacent an interior surface, the interior surface being between the first dielectric substrate and the second dielectric substrate, a hole disposed through the second dielectric substrate, the hole substantially aligned with a portion of the signal trace line, an electrical conductor disposed within the hole, and a solder joint formed between a first terminal end of the electrical conductor and the portion of the signal trace line.

In some embodiments, the electrical conductor is a segment of solid wire having a loose fit relative to a wall of the hole. The wire may be copper.

Some embodiments include an electrical component having a portion soldered to a second terminal end of the electrical conductor, the electrical component being at least one of a signal terminal, an electrical connector, a cable, and an electromagnetic radiator. In various embodiments, the signal trace line is configured to convey a radio frequency signal to or from the electrical component via the electrical conductor. In various embodiments, the electrical component is surface mounted to an exterior surface of one of the second dielectric substrate or a further substrate bonded directly or indirectly to the second dielectric substrate.

Still other aspects, examples, and advantages are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment. Various aspects and embodiments described herein may include means for performing any of the described methods or functions.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the disclosure. In the figures, each identical or nearly identical component that is illustrated in various figures may be represented by a like numeral. For purposes of clarity, not every component may be labeled in every figure. In the figures:

FIG. 1 is a schematic diagram of one example of an electromagnetic circuit structure;

FIG. 2 is a schematic diagram of another example of an electromagnetic circuit structure;

FIG. 3 is an exploded view of the electromagnetic circuit structure of FIG. 1 illustrating certain aspects of an assembly method of the electromagnetic circuit structure of FIG. 1;

FIG. 4 is an exploded view of the electromagnetic circuit structure of FIG. 2 illustrating certain aspects of an assembly method of the electromagnetic circuit structure of FIG. 2; and

FIG. 5 is a flow diagram of an example of a generalized method of assembly of an electromagnetic circuit structure.

### DETAILED DESCRIPTION

Aspects and examples described herein provide inter-layer signal conveyance within various circuits, suitable for various circuit board manufacturing, including radio frequency circuit embodiments. The aspects and examples described herein advantageously apply additive and subtractive manufacturing techniques to provide structures for conveyance of a signal between layers, which may convey a signal from various circuit components or features to other circuit components or features. In some embodiments, a vertical launch structure may feed a signal to a radiator (e.g., an antenna), and likewise receive a signal from the radiator, which may be part of an array of radiating elements. In some embodiments, a vertical launch structure may feed a signal to a connector, a waveguide, a cable, etc. to be conveyed to further circuit components or features. In some embodiments, a vertical launch structure may feed a signal to (or receive a signal from) a signal divider (or combiner), which may be part of a beamformer for an array of radiating elements. Various embodiments may employ a vertical launch structure to convey a signal to various other circuit components or features.

Manufacturing processes described herein may be particularly suitable for fabrication of such circuit structures having small circuit features capable of supporting electromagnetic signals in the range of 8 to 75 GHz or more, for example, and up to 300 GHz or more, using suitable subtractive (e.g., milling, drilling) and additive (e.g., 3-D printing, filling) manufacturing equipment. Electromagnetic circuit structures in accord with systems and methods described herein may be particularly suitable for application in 28 to 70 GHz systems, including millimeter wave communications, sensing, ranging, etc. Aspects and embodiments described may also be suitable for lower frequency applications, such as in the S-band (2-4 GHz), X-band (8-12 GHz), or others.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, end, side, vertical and horizontal, and the like, are intended for convenience of description, not to limit the present systems and methods or their components to any one positional or spatial orientation.

The term “radio frequency” as used herein is not intended to be limited to a particular frequency, range of frequencies, band, spectrum, etc., unless explicitly stated and/or specifically indicated by context. Similarly, the terms “radio frequency signal” and “electromagnetic signal” are used interchangeably and may refer to a signal of various suitable frequency for the propagation of information-carrying signals, for any particular implementation. Such radio frequency signals may generally be bound at the low end by frequencies in the kilohertz (kHz) range, and bound at the high end by frequencies of up to hundreds of gigahertz (GHz), and explicitly includes signals in the microwave or millimeter wave ranges. Generally, systems and methods in accord with those described herein may be suitable for handling non-ionizing radiation, at frequencies below those conventionally handled in the field of optics, e.g., of lower frequency than, e.g., infrared signals.

Various embodiments of radio frequency circuits may be designed with dimensions selected and/or nominally manufactured to operate at various frequencies. The selection of appropriate dimensions may be had from general electromagnetic principles and are not presented in detail herein.

The methods and apparatuses described herein may support smaller arrangements and dimensions than conventional processes are capable. Conventional circuit boards may be limited to frequencies below about 30 GHz. The methods and apparatuses described herein may allow or accommodate the manufacture of electromagnetic circuits of smaller dimensions, suitable for radio frequency circuits intended to be operated at higher frequencies, using safer and less complex manufacturing, at lower cost.

Electromagnetic circuits and methods of manufacture in accord with those described herein include various additive and subtractive manufacturing techniques to produce electromagnetic circuits and components capable of handling higher frequencies, with lower profiles, and at reduced costs, cycle times, and design risks, than conventional circuits and methods. Examples of techniques include machining (e.g., milling) of conductive material from a surface of a substrate to form signal traces (e.g., signal conductors, striplines) or apertures, which may be of significantly smaller dimensions than allowed by conventional PCB processes, machining of one or more substrates to form a trench, using 3-dimensional printing techniques to deposit printed conductive inks into the trench to form a continuous electric barrier (e.g., a Faraday wall) (e.g., as opposed to a series of ground vias that require minimum spacing), “vertical launch” signal paths formed by machining (such as milling, drilling, or punching) a hole through a portion of substrate and in which a wire is placed (and/or conductive ink is printed) to make electrical contact to a signal trace disposed on a surface of the substrate (or an opposing substrate), and using 3-dimensional printing techniques to deposit printed resistive inks to form resistive components.

Any of the above example techniques and/or others (e.g., soldering and/or solder reflow), may be combined to make various electromagnetic components and/or circuits. Aspects and examples of such techniques are described and illustrated herein with respect to a radio frequency interconnect to contain and convey an electromagnetic signal along a layer of an electromagnetic circuit in one dimension and vertically through to other layers of the circuit in another dimension. The techniques described herein may be used to form various electromagnetic components, connectors, circuits, assemblies, and systems.

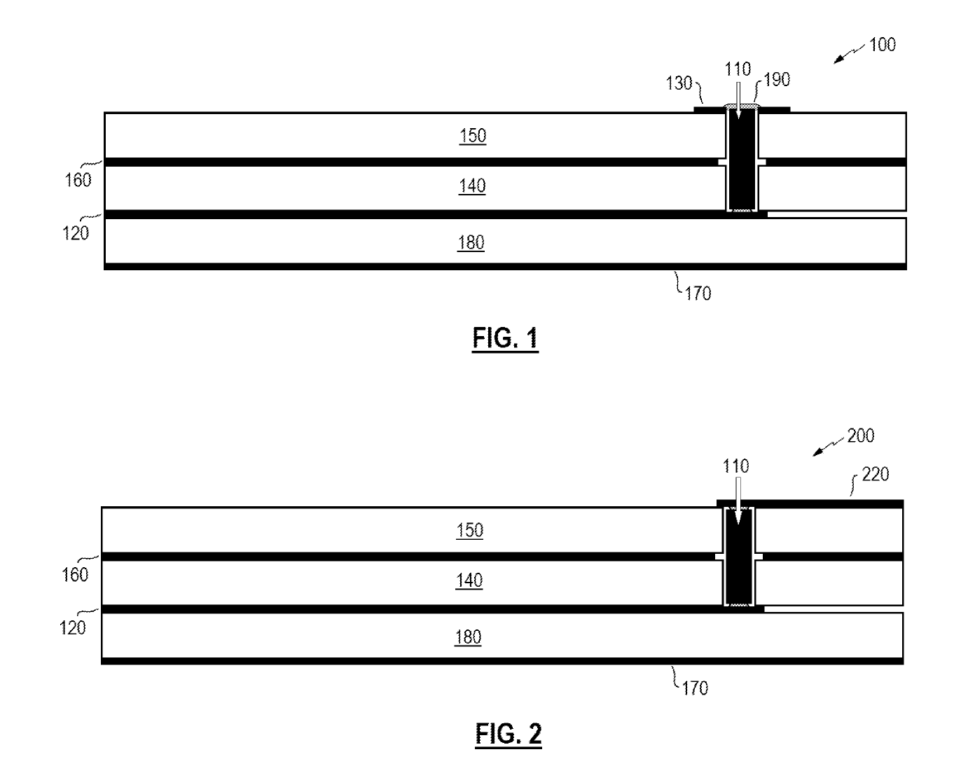

FIG. 1 illustrates an example of an electromagnetic circuit structure 100 in a cross-sectional edge view, that includes a conductor 110 configured to convey signals, such as radio frequency or other signals, from a signal trace 120 (e.g., a conductive line disposed on a substrate) to a signal terminal 130 disposed at a different layer of the circuit structure 100. The conductor 110 may equivalently convey one or more signals from the signal terminal 130 to the signal trace 120, and may convey one or more signals in both directions at the same time (e.g., bidirectional) in various embodiments. The conductor 110 may provide an electrical connection between the signal trace 120 and the signal terminal 130 for any of various purposes in keeping with various electromagnetic circuit applications. The signal trace 120 and the signal terminal 130 are not intended to be limited to any particular form, and in various embodiments may be any of various forms, and may be a circuit component (such as a radiating element or antenna, for example), a terminal pad, a surface connection pad (e.g., for surface mounting a connector or a cable, for example), or may be signal traces that convey the signal(s) to and/or from other components, or may take on other purposes and forms.

In various embodiments, the conductor 110 is inserted into an opening in one or more substrates and/or layers of the circuit structure 100, and may be physically and electrically secured by a solder joint, such as by direct application of a solder joint (e.g., solder 190) and/or by application of a solder bump (e.g., tinning) at one or more locations or surfaces followed by a solder reflow operation at some point during the manufacturing process. Accordingly, the conductor 110 is not required to be compression or force fit inside the opening (hole), and may have a loose fit relative to the wall(s) of the opening. In the example of FIG. 1, a terminal end of the signal trace 120 aligns with one end of the opening in which the conductor 110 is disposed, and the terminal end of the signal trace 120 is a terminal pad to which the conductor 110 may be soldered.

In various embodiments, one or more openings in one or more substrates to accommodate the conductor 110 may be formed by milling or drilling a hole appropriately sized to accommodate the conductor 110. The conductor 110 may be a wire, such as a copper or other conductive wire, which may be solid, hollow, single-stranded, or multi-stranded. As illustrated in FIG. 1, the circuit structure 100 may include one or more intermediate substrates 140, 150 between the signal trace 120 and the signal terminal 130. In various embodiments, a hole may be milled (e.g., drilled) in each of the intermediate substrates 140, 150 to accommodate the conductor 110, and the intermediate substrates 140, 150 may be bonded (e.g., via an adhesive, not shown) to each other. In various embodiments, the milled hole(s) and/or the conductor 110 may be as small as about 5 mils (0.005 inches) in diameter, or even as small as about 2 or 3 mils with suitable machining equipment. Further, in various embodiments, the signal trace 120 may be formed by milling away a conductive layer, such as an electroplated copper layer, disposed on a substrate, and may be as small as about 5 mils or smaller in width.

In various embodiments there may be circuit components between various intermediate substrates 140, 150, such as the ground plane 160 shown in FIG. 1, or other signal traces or components (e.g., resistors, inductors, capacitors, radiators, signal dividers, etc.) between various intermediate substrates, such as the intermediate substrates 140, 150. The signal trace 120, conductor 110, signal terminal 130, ground plane 160, etc., as illustrated in FIG. 1 represents a cross section of merely one possible embodiment. Various embodiments have additional features, components, and/or structures at other cross-sectional locations (e.g., into or out of the plane of the figure) that for simplicity are not illustrated in the figures. Various embodiments may have additional intermediate substrates through which the conductor 110 may provide signal conveyance. Accordingly, various embodiments may have multiple layers of dielectric, ground planes, signal traces, and associated other circuit components.

The example shown in FIG. 1 further includes a ground plane 170, e.g., on an opposing face of a substrate 180, such that the signal trace 120 is provided with a pair of ground planes 160, 170 (e.g., above and below the signal trace 120 as shown). For example, the ground planes 160, 170 may be an electroplated material, such as copper, disposed on one or more surfaces of a respective substrate (e.g., the substrates 140, 150, 180). In various embodiments, materials and thicknesses of, e.g., the substrates 140, 180, may be selected to maintain a characteristic impedance for signals conveyed by the signal trace 120, which selection may also be based upon a range of frequencies for the signals conveyed. Additionally, a width (not illustrated) of the signal trace 120 may be selected for conveyance of various signal frequencies, e.g., to maintain a characteristic impedance, attenuation, etc. The ground planes 160, 170 may maintain an electromagnetic boundary condition (e.g., ground) with respect to which various signals conveyed by the signal trace 120 may be represented.

In some embodiments, further ground planes or structures may be included in the circuit structure 100, not in the plane of FIG. 1. For example, there may be one or more conductive walls (e.g., Faraday walls, vertically with respect to FIG. 1) to either side of the signal trace 120 (e.g., behind or in front of the plane of FIG. 1, substantially parallel to the plane of FIG. 1, and perpendicular to the ground planes 160, 170) and extending between the ground plane 160 and the ground plane 170, such that at least a portion of the signal trace 120 may be surrounded on four sides by an electromagnetic boundary, e.g., ground planes 160, 170 above and below, and Faraday walls to either side, along a length of the signal trace 120. For example, one or more vertical trenches may be milled through the substrates 140, 180, from the ground plane 170 to the ground plane 160 (in a different plane than that of FIG. 1), and the trenches may be filled with a conductive material, such as a conductive ink, which may be 3-D printed in some embodiments, for example. Electrical connectivity of such Faraday walls may be made with the ground planes 160, 170 via the conductive ink being placed in contact with the ground planes 160, 170 (e.g., the trench milled without piercing the conductor of the ground plane) or may be formed by a soldering step of a manufacturing process, or a combination of the two and/or other techniques. Further details of at least one example of a Faraday wall and its manufacture are disclosed in U.S. Provisional Patent Application No. 62/673,491 titled ADDITIVE MANUFACTURING TECHNOLOGY (AMT) FARADAY BOUNDARIES IN RADIO FREQUENCY CIRCUITS filed on May 18, 2018, which is hereby incorporated herein by reference for all purposes.

FIG. 2 illustrates another example of an electromagnetic circuit structure 200 in accord with aspects and embodiments described herein. The circuit structure 200 is similar to the circuit structure 100 of FIG. 1, but the conductor 110 in the example of the circuit structure 200 provides signal conveyance between the signal trace 120 and another signal trace 220. In various embodiments, a further substrate may be provided and bonded to the substrate 150 to provide a further ground plane, e.g., above the signal trace 220 and on an opposing side of the signal trace 220 from the ground plane 160. Additionally, various embodiments may include one or more Faraday walls to provide additional electromagnetic boundary conditions to signals conveyed by the signal trace 220, as described above.

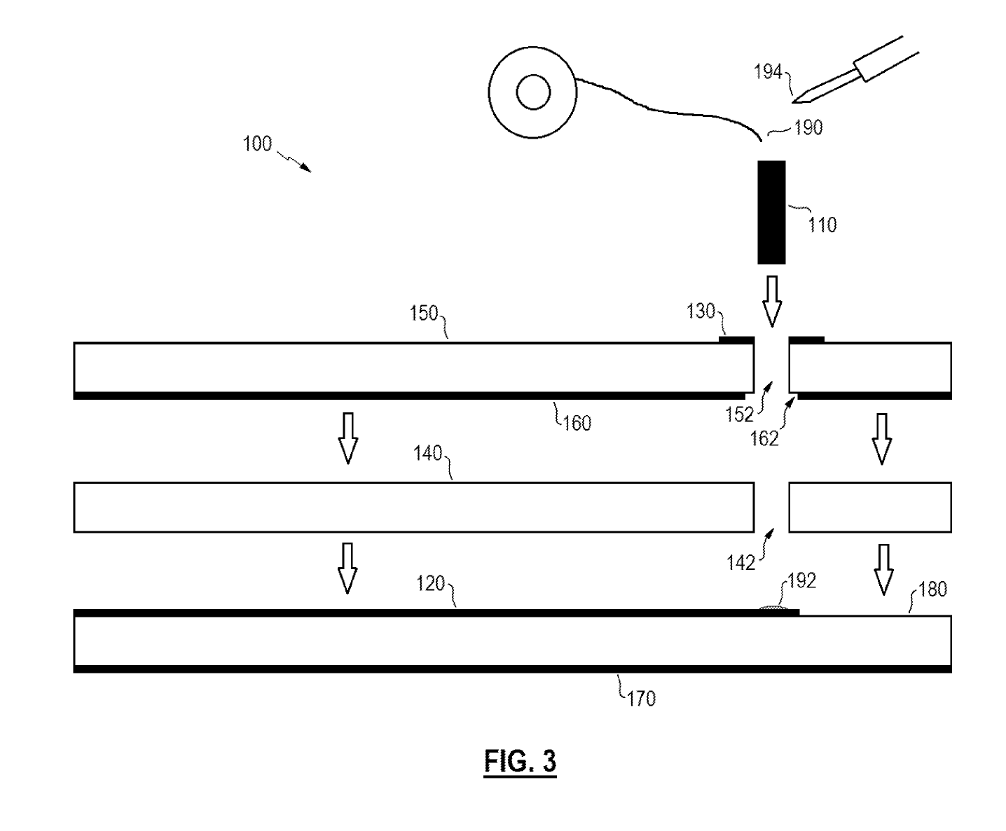

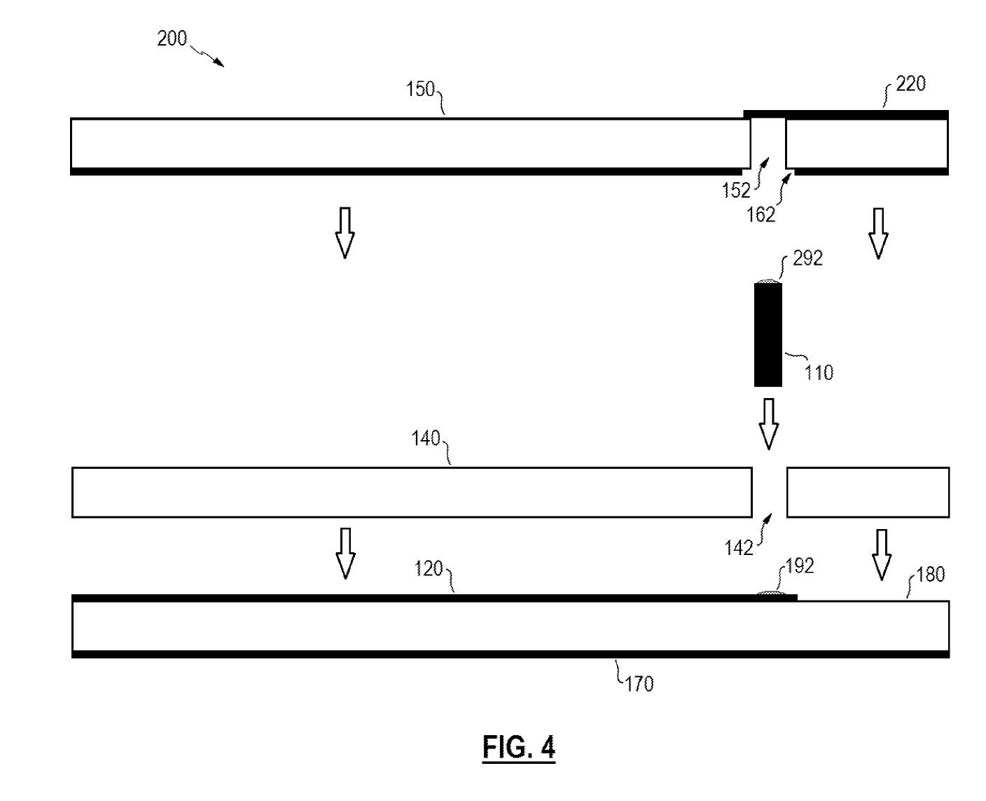

Various manufacturing methods to provide a “vertical launch” inter-layer signal connection, disposed among various substrates and circuit layers in accord with aspects and embodiments herein, are described with respect to FIGS. 3 and 4.

FIG. 3 illustrates an expanded view of the circuit structure 100. Various embodiments may begin with the substrate 180 having electrical conducting material disposed on opposing faces, such as an electroplated conducting material, such as copper. A signal trace 120 may be formed from at least one of the faces of conducting material by milling away excess conductive material to form the signal trace 120. The signal trace 120 may be milled to a suitable width for a particular signal type, which may be based in part upon a range of frequencies for which the signal trace 120 may be used. As described above, a thickness and material of the substrate 180 may also be selected such that in combination with the ground plane 170, e.g., the conducting material disposed upon the opposing face of the substrate 180, a characteristic impedance may be maintained for signals conveyed by the signal trace 120. In some embodiments, a solder bump 192 may be applied to a terminal end of the signal trace 120, and may be a solder tinning of the terminal end. Alternatively or additionally, a solder bump or solder tinning may be applied to the conductor 110, on an end of the conductor 110 intended to make contact with the terminal end of the signal trace 120.

The substrate 140 may then be bonded to the substrate 180, via a bonding material (e.g., adhesive) of various types and bonding methods. A hole 142 is milled through the substrate 140 to provide access to the terminal end of the signal trace 120 (and the solder bump 192). In various embodiments, the hole 142 may be milled before bonding the substrate 140 to the substrate 180, or after.

The substrate 150 may be provided with electrical conducting material disposed on opposing faces, similar to the substrate 180 as described above. One face of conducting material may become the ground plane 160. A portion of conducting material on the opposing face of the substrate 150 may become the signal terminal 130. In some embodiments, the signal terminal 130 may be formed by milling away some conducting material from the respective face of the substrate 150. In other embodiments, the signal terminal 130 may be formed by other means. In some embodiments, as described above, the signal terminal 130 may be or include differing structures and/or circuit components. For example, the signal terminal 130 may be a radiator having any of various shapes disposed on the surface of the substrate 150, such as a linear or spiral signal trace configured to radiate electromagnetic energy, e.g., when fed with an appropriate signal by the conductor 110. In other embodiments, the signal terminal 130 may be a surface mounting point for a connector or a cable, or may be or form a portion of a second signal trace, such as the signal trace 220 of the circuit structure 200, for example. In various embodiments, differing structures may be included at or near the position of the signal terminal 130 illustrated in FIG. 3 and may be configured for suitable electrical coupling with the conductor 110. The “vertical launch” conductor 110 and methods described herein are not intended to be limited by the circuit components between which the conductor 110 is configured to convey a signal. Accordingly, each of the signal trace 120 and the signal terminal 130 is merely an example of a circuit component which the circuit structures and methods described herein may include.

With continued reference to the example of an assembly process illustrated by FIG. 3, a portion 162 of conducting material may be milled away (e.g., removing a portion of the ground plane 160) where a hole 152 may be milled through the substrate 150. The hole 152 is configured to accommodate the conductor 110, to provide access to the hole 142, through which access is provided to the terminal end of the signal trace 120 (and the solder bump 192, if included). The milled away portion 162 provides a clearance between the conductor 110 and the ground plane 160 such that no electrical connection is made between the conductor 110 and the ground plane 160 upon final assembly, for example.

The substrate 150 (and/or an exterior surface of the ground plane 160) may be bonded to the substrate 140. The ground plane 160 may thereby be encapsulated between the substrate 140 and the substrate 150. Once bonded, the holes 142, 152 may form a substantially continuous opening through the substrates 140, 150 to provide access to the terminal end of the signal trace 120 (and the solder bump 192). The conductor 110 may be inserted into the holes 142, 152. Heat 194 (e.g., from a soldering tool) may be applied to the solder 190 to form a secure electrical connection between one end of the conductor 110 and the signal terminal 130. The applied heat 194 may be conveyed through the conductor 110 to the other end of the conductor 110, which may reflow the solder bump 192 applied to terminal end of the signal trace 120 or, optionally, may reflow a solder bump that was previously applied to the other end of the conductor 110. Accordingly, reflowed solder may form a secure electrical connection between the terminal end of the signal trace 120 and the conductor 110.

Numerous variations to the above method of manufacture (or assembly) of the electromagnetic circuit structure 100 may be included among various embodiments. For example, the substrates 140, 150 may be bonded together prior to milling holes 142, 152, such that a single hole may be milled through the bonded combination of the substrates 140, 150. Further, the substrates 180, 140, 150 may all be bonded together prior to milling a hole through the substrate 140, 150 to provide access to the terminal end of the signal trace 120. The ground plane 160 may be formed as a conductive material disposed upon the substrate 140 rather than upon the substrate 150, or the ground plane 160 may be a laminate layer bonded to each of the substrates 140, 150 during manufacture, e.g., not previously disposed upon either of the substrates 140, 150. In other embodiments, a ground plane 160 may be excluded. The signal trace 120 may be formed out of a conductive material disposed upon the substrate 140 rather than upon the substrate 120. As described above, a solder bump may be placed on the conductor 110 where it is to make electrical contact with the signal trace 120, instead of or in addition to the solder bump 192 illustrated on the signal trace 120. Those of skill in the art, with the benefit of this disclosure, may identify numerous variations to the various components and methods that may yield a “vertical launch” conductor, configured to convey signals between layers of a circuit, in keeping with aspects and embodiments described herein.

FIG. 4 illustrates an expanded view of the circuit structure 200 to illustrate various manufacturing methods to provide a “vertical launch” inter-layer signal connection. Various milling, soldering, and inserting (e.g., of a conductor 110) are similar to those described above with respect to FIG. 3. The circuit structure 200, however, may be configured to convey a signal between two signal traces 120, 220. In this example of a circuit structure 200 it may be desirable not to pierce the conductive material that forms the signal trace 220, which may be formed by milling away a conductive material on the surface of the substrate 150. Accordingly, the hole 152 may be milled from one side of the substrate 150 toward the signal trace 220 without continuing through the signal trace 220. If, as in this example, the signal trace 220 is formed from conductive material disposed upon the substrate 150, it may not be possible to place a solder bump on a terminal end of the signal trace 220. Instead, and as illustrated, a solder bump 292 may be placed on the conductor 110 where it will make contact with the signal trace 220 upon final assembly. A solder reflow operation may include an oven or baking process that heats most or all of the components shown in FIG. 4 and thereby reflows the solder bumps 192, 292 to form a secure electrical connection between the conductor 110 and the respective signal trace 120, 220.

Further, as in the above described method options with respect to FIG. 3, numerous variations to the method of manufacture (or assembly) of the electromagnetic circuit structure 200 may be included among various embodiments. For example, various embodiments may include bonding the substrate 140 to the substrate 180 prior to milling the hole 142. The substrate 150 may be bonded to the substrate 140 prior to bonding to the substrate 180, and the holes 142, 152 may be milled through a bonded combination of the substrate 140, 150, or may be milled through each of substrates 140, 150, respectively, separate from each other. As above, those of skill in the art, with the benefit of this disclosure, may identify further variations to the various components and methods that may yield a “vertical launch” connection configured to convey signals between layers of a circuit, in keeping with aspects and embodiments described herein.

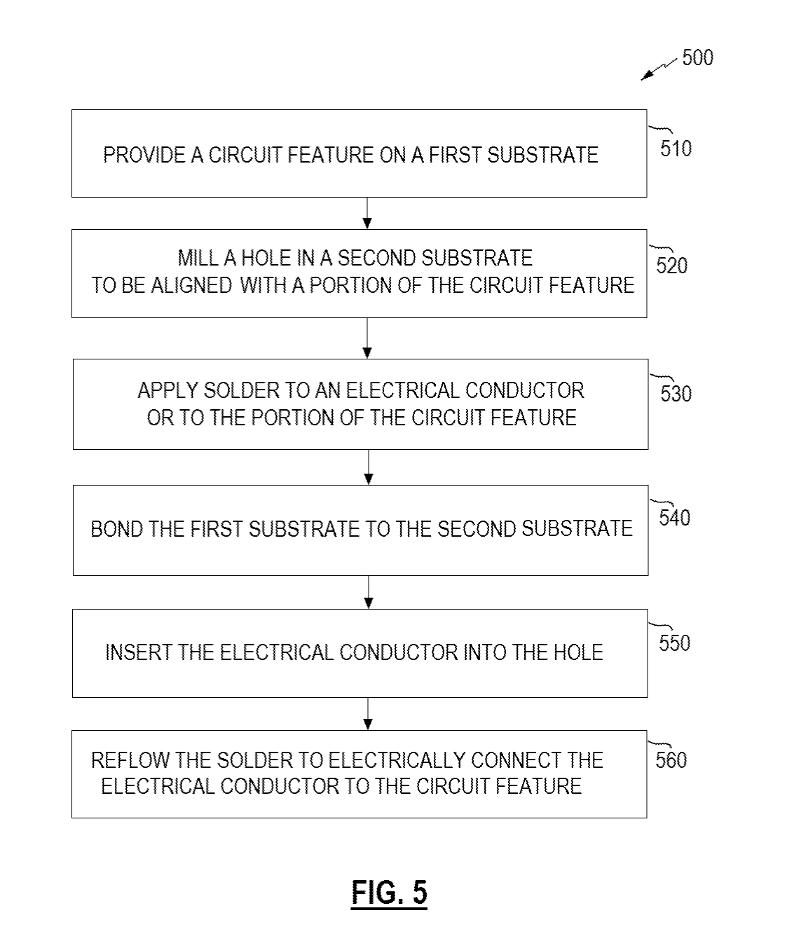

FIG. 5 illustrates an example of a generalized method 500 of forming a vertical launch connection between layers of a circuit, e.g., a layer-to-layer connection, in accord with aspects and embodiments herein. A circuit feature is provided on a substrate (block 510), the circuit feature is one to which a vertical connection is desired. A hole is milled (block 520) in another substrate that will be bonded to the first substrate. The hole is positioned to align with a portion of the circuit feature to which the electrical connection is to be made. For example, the circuit feature may be a signal trace line, and the portion with which the hole aligns may be a terminal end of the signal trace line. The hole may be sized to accommodate an electrical conductor that will form part of the electrical connection. Solder is applied (block 530) to either (or both) of the electrical conductor and the portion of the circuit feature. The circuit feature, the two substrates, and the electrical conductor are assembled by bonding the substrates (block 540) and inserting the electrical conductor into the hole (block 550), and a solder reflow operation is performed (block 560) to make electrical connection between the portion of the circuit feature and the electrical conductor. Various of the process blocks of FIG. 5 may be performed in various orders, and in some embodiments various of the process blocks may be repeated, such as for a more complex circuit, e.g., having multiple substrates and/or vertical launch connections. As discussed above, one or more holes may be milled before or after bonding, solder may be applied at various suitable points in such a process, and circuit features may be formed at differing points in a process, etc.

In various embodiments, bonding may include a heating process, and a solder reflow may be achieved with the same heating process in some embodiments. For example, two or more substrates may be positioned and/or aligned for bonding, with an adhesive or bonding material disposed between, and an electrical conductor may be inserted through one or more holes, and such an assembly may be heated to complete both bonding and solder reflow. In some embodiments, additional substrates may be positioned and/or aligned before heating, such that an electrical conductor (with solder tinning on the conductor or on portions of various circuit features) may be disposed within or encapsulated by a multi-layer electromagnetic circuit structure, and bonding of various layers and reflow of various solder bumps/tinning may be achieved with one or more heating steps or processes.

Further advantages of systems and methods described herein may be realized. For example, conventional PCB manufacturing may impose limitations on circuit feature sizes, such as the width of signal traces and the diameter of through-holes for inter-layer connections which, in comparison with systems and method described herein, may limit the highest frequencies for which conventionally made electromagnetic circuits may be suitable. Aspects and embodiments herein, however, allow substantially smaller signal traces and smaller “vertical launch” connections, formed using less complex manufacturing methods, than conventional PCB manufacturing techniques.

Further, substrate thicknesses impact characteristic impedance (e.g., due to the distance to ground planes disposed upon opposing surfaces), in relation to width of signal traces, such that wider traces required by conventional PCB processes cause selection of thicker substrates, which may limit how thin the circuit can be manufactured. For example, general recommendations under conventional PCB manufacturing include total thicknesses of about 60 mil (0.060 inches). By comparison, electromagnetic circuits in accord with aspects and embodiments described, using subtractive and additive manufacturing techniques, can result in circuit boards having a low profile down to a thickness of about 10 mil or less, with signal line traces having widths of about 4.4 mil, or 2.7 mil, or less, with inter-layer “vertical launch” connections being accordingly small diameters, and interconnect geometries substantially flush with a surface of the board.

Various electromagnetic circuits and methods in accord with aspects and embodiments described herein, using various subtractive and additive manufacturing techniques, allow for electrically continuous structures to connect ground planes. Accordingly, an electrically continuous structure may be provided and disposed vertically through one or more substrates, (e.g., between opposing surfaces of the substrate) to form “Faraday walls” that confine electric fields. In various embodiments, such Faraday walls may electrically couple two or more ground planes. Further in various embodiments, such Faraday walls may confine and isolate electromagnetic fields from neighboring circuit components. In some embodiments, such Faraday walls may enforce a boundary condition to limit electromagnetic signals to be locally transverse electric-magnetic (TEM) fields, e.g., limiting signal propagation via a signal trace line to a TEM mode.

In various embodiments, various subtractive (milling, drilling), additive (printing, filling, inserting), and adherent (bonding) steps may be carried out, in various orders, with soldering and reflow operations as necessary, to form an electromagnetic circuit having one or any number of substrate layers, that may include one or more vertical (e.g., inter-layer) signal connections in accord with those described herein, and may include radiators, receptors, Faraday walls, signal traces, terminal pads, or other features.

A generalized method for making any of various electromagnetic circuits includes milling a conductive material disposed on a substrate to form circuit features, printing (or depositing, e.g., via 3-D printing, additive manufacturing techniques) additional circuit features, such as resistors formed of resistive ink, for example, depositing solder on any feature, as necessary, milling (or drilling) through substrate material (and/or conductive materials) to form openings, such as holes, voids, or trenches, and depositing or printing (e.g., via 3-D printing, additive manufacturing techniques) conductive material (such as conductive ink or a wire conductor) into the holes, voids, trenches, for example to form vertical signal launches as described herein, or to form Faraday walls or other circuit structures. Any of these steps may be done in different orders, repeated, or omitted as necessary for a given circuit design, and to build up layers such as may include bonding steps to adhere one substrate or layer to the next, and continuing with repeated steps as necessary. Accordingly, in some embodiments, multiple substrates may be involved in the manufacture of an electromagnetic circuit, and the method includes bonding further substrates as necessary, further milling and filling operations, and further soldering and/or reflow operations.

Having described several aspects of at least one embodiment of a vertical signal launch and a method for manufacturing the same or other electromagnetic circuits, the above descriptions may be employed to produce various electromagnetic circuits having very low profiles, such as thicknesses of 10 mils (0.010 inches, 254 microns) or less, and may include signal traces as narrow as 4.4 mils (111.8 microns), 2.7 mils (68.6 microns), or even as narrow as 1.97 mils (50 microns) or less, depending upon tolerances and accuracy of various milling and additive manufacturing equipment used. Accordingly, electromagnetic circuits in accord with those described herein may be suitable for X-Band and higher frequencies, with various embodiments capable of accommodating frequencies over 28 GHz, and up to 70 GHz or higher. Some embodiments may be suitable for frequency ranges up to 300 GHz or more.

Additionally, electromagnetic circuits in accord with those described herein may have a low enough profile, with accordant light weight, to be suitable for outer space applications, including folding structures to be deployed by unfolding when positioned in outer space.

Further, electromagnetic circuits manufactured in accord with methods described herein accommodate less expensive and faster prototyping, without the necessity for caustic chemicals, masking, etching, bathing, electroplating, etc. Simple substrates with pre-plated conductive material disposed on one or both surfaces (sides) may form the core starting material(s), and all elements of an electromagnetic circuit may be formed by milling (subtractive, drilling), filling (additive, inserting, printing of conductive and/or resistive inks), and bonding one or more substrates. Simple solder reflow operations and insertion of simple conductors (e.g., copper wire) are accommodated by methods and systems described herein.

Further, electromagnetic circuits manufactured in accord with methods described herein may accommodate deployment on, or designs calling for, non-planar surfaces. Thin, low-profile electromagnetic circuits, such as described herein and others, may be manufactured using mill, fill, and bond techniques as described herein to produce electromagnetic circuits having various contours to accommodate changing applications, to conform to a surface (such as a vehicle) or to support complex array structures, for example.

Having thus described several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only.

What is claimed is:

1. A circuit board, comprising:
a first substrate having a first surface;
a second substrate having a second surface; the second surface facing the first surface;
a hole disposed through the first substrate;
an electrical component disposed adjacent each of the first surface and the second surface, the electrical component being at least partially encapsulated between the first substrate and the second substrate, the electrical component having a portion substantially aligned with the hole; and
an electrical conductor disposed within the hole, the electrical conductor having a first terminal end and a second terminal end, the first terminal end soldered to the portion of the electrical component.

2. The circuit board of claim 1 wherein the electrical conductor is a solid wire.

3. The circuit board of claim 1 wherein the electrical component is a signal trace line formed of an electrically conductive material, and the portion substantially aligned with the hole forms a terminal covering to the hole.

4. The circuit board of claim 3 further comprising a second electrical component having a portion soldered to the second terminal end of the electrical conductor.

5. The circuit board of claim 4 wherein the second electrical component is one of a signal terminal, an electrical connector, a cable, and an electromagnetic radiator.

6. The circuit board of claim 5 wherein the second electrical component is surface mounted to a third surface.

7. The circuit board of claim 4 wherein the second electrical component is substantially encapsulated between two substrates.

8. The circuit board of claim 3 further comprising a ground plane disposed adjacent an opposing surface of the second substrate, the ground plane configured to provide an electromagnetic boundary condition to the signal trace line.

9. A method of manufacturing an electromagnetic circuit, the method comprising:
providing a circuit feature upon a surface of at least one of a first substrate or a second substrate;
forming a hole in at least one of the first substrate or the second substrate, the hole positioned to substantially align with a portion of the circuit feature;
applying solder to at least one of an electrical conductor and the portion of the circuit feature;
bonding the first substrate, directly or indirectly, to the second substrate, a bonded orientation of the first substrate and the second substrate being configured to at least partially encapsulate the circuit feature between the first substrate and the second substrate and to substantially align the hole with the portion of the circuit feature, the hole being positioned to provide access to the portion of the circuit feature;
inserting the electrical conductor in the hole; and
reflowing the solder to form an electrical connection between the electrical conductor and the portion of the circuit feature.

10. The method of claim 9 wherein inserting the electrical conductor in the hole comprises inserting a segment of solid wire into the hole.

11. The method of claim 9 wherein providing the circuit feature upon a surface comprises milling an electrically conductive material from the surface to form the circuit feature.

12. The method of claim 11 wherein milling an electrically conductive material from the surface to form the circuit feature comprises milling the electrically conductive material to form a signal trace line.

13. The method of claim 9 wherein the circuit feature is a first circuit feature and further comprising providing a second circuit feature having a second portion positioned to substantially align with an opposing opening of the hole, and applying solder to form an electrical connection between the electrical conductor and the second portion.

14. The method of claim 13 wherein providing the second circuit feature comprises milling an electrically conductive material to form an electromagnetic radiator.

15. The method of claim 12 wherein providing the second circuit feature comprises milling an electrically conductive material to form a signal terminal pad configured to be coupled to at least one of an electrical connector or an electrical cable.

16. A circuit board, comprising:
a first dielectric substrate bonded directly or indirectly to a second dielectric substrate;
a signal trace line formed of an electrically conductive material disposed adjacent an interior surface, the interior surface being between the first dielectric substrate and the second dielectric substrate;
a hole disposed through the second dielectric substrate, the hole substantially aligned with a portion of the signal trace line;
an electrical conductor disposed within the hole; and
a solder joint formed between a first terminal end of the electrical conductor and the portion of the signal trace line.

17. The circuit board of claim 16 wherein the electrical conductor is a segment of solid wire having a loose fit relative to a wall of the hole.

18. The circuit board of claim 16 further comprising an electrical component having a portion soldered to a second terminal end of the electrical conductor, the electrical component being at least one of a signal terminal, an electrical connector, a cable, and an electromagnetic radiator.

19. The circuit board of claim 18 wherein the signal trace line is configured to convey a radio frequency signal to or from the electrical component via the electrical conductor.

20. The circuit board of claim 18 wherein the electrical component is surface mounted to an exterior surface of one of the second dielectric substrate or a further substrate bonded, directly or indirectly, to the second dielectric substrate.
